(19) United States
(12) Patent Application Publication
(10) Pub. No.: US 2026/0040795 A1
(43) Pub. Date: Feb. 5, 2026

(54) DISPLAY DEVICE

(71) Applicant: Samsung Display Co., LTD., Yongin-si (KR)

(72) Inventors: JINGYU SIM, Yongin-si (KR); SANGHOON KIM, Yongin-si (KR); BYUNGHOON KANG, Yongin-si (KR); HYUNJI LEE, Yongin-si (KR); TAEHYEOG JUNG, Yongin-si (KR); SEONGJIN HWANG, Yongin-si (KR)

(21) Appl. No.: 19/209,219

(22) Filed: May 15, 2025

(30) Foreign Application Priority Data
Aug. 1, 2024 (KR) 10-2024-0102736

(51) Int. Cl. H10K 59/80; H10K 102/00

(52) U.S. Cl. CPC H10K 59/873; H10K 2102/311

(57) ABSTRACT

A display device includes a folding area foldable around a folding axis on a plane, and a non-folding area adjacent to the folding area. The display device includes a display panel including a plurality of light emitting elements, and a window disposed on the display panel and including a patterned glass. The patterned glass includes a patterned portion corresponding to the folding area and having one surface in which a plurality of first groove patterns extending in a first direction and arranged in a second direction perpendicular to the first direction are defined, and a non-patterned portion adjacent to the patterned portion and corresponding to the non-folding area. The folding area includes a plurality of first areas corresponding to the plurality of light emitting elements, respectively, and arranged in the second direction, and a peripheral area adjacent to the plurality of first areas, and satisfies Equation 1 or 2.

This application claims priority to Korean Patent Application No. 10-2024-0102736, filed on Aug. 1, 2024, and all the benefits accruing therefrom under 35 U.S.C. § 119, the content of which in its entirety is herein incorporated by reference.

### BACKGROUND

### (1) Field

The present disclosure herein relates to a display device, and more particularly, to a foldable display device.

### (2) Description of the Related Art

Display devices display various images on display screens to provide information for users. The display devices generally display the information within assigned screens.

Recently, flexible display devices including flexible display panels capable of being folded are being developed. The flexible display devices may be folded, rolled, or bent unlike rigid display devices. The flexible display devices that may be variously changed in shape are portable regardless of the sizes of existing screens, and thus users' convenience may be improved.

### SUMMARY

The present disclosure provides a display device including a window with high visibility.

An embodiment of the invention provides a display device including a folding area foldable around a virtual folding axis on a plane, and a non-folding area adjacent to the folding area, and the display device includes a display panel including a plurality of light emitting elements, and a window disposed on the display panel and including a patterned glass. In such an embodiment, the patterned glass includes a patterned portion corresponding to the folding area and having one surface in which a plurality of first groove patterns extending in a first direction and arranged in a second direction perpendicular to the first direction are defined, and a non-patterned portion adjacent to the patterned portion and corresponding to the non-folding area. In such an embodiment, the folding area includes a plurality of first areas corresponding to the plurality of light emitting elements, respectively, and arranged in the second direction, and a peripheral area adjacent to the plurality of first areas, and satisfies Equation 1 or 2 below.

$$\frac{{N}_{a}}{{N}_{g}} = n \qquad [ Equation 1 ]$$

$$\frac{{N}_{a}}{{N}_{g}} = \frac{1}{n} \qquad [ Equation 2 ]$$

In Equations 1 and 2, N_{g} a denotes the number of the plurality of first groove patterns arranged in the second direction, Nₐ denotes the number of the plurality of first areas arranged in the second direction, and n is an integer of 1 or greater.

In an embodiment, the window may further include a filling layer filled in the first groove patterns.

In an embodiment, the plurality of first groove patterns may correspond to the plurality of first areas, respectively.

In an embodiment, the plurality of first areas may emit first light, the folding area may further include a plurality of second areas which emits second light, and a plurality of third areas which emits third light, and the peripheral area may surround each of the plurality of first areas, the plurality of second areas, and the plurality of third areas.

In an embodiment, the plurality of first groove patterns may correspond to the plurality of second areas, respectively, or correspond to the plurality of third areas, respectively.

In an embodiment, the folding area may include a first pixel row including the plurality of first areas arranged in the second direction, and a second pixel row in which the plurality of second areas and the plurality of third areas are arranged alternately with each other in the second direction, where the second pixel row may be spaced apart from the first pixel row in the second direction.

In an embodiment, the plurality of first groove patterns may be defined in a top surface of the patterned portion, and a plurality of second groove patterns extending in the first direction and arranged in the second direction may be defined in a bottom surface of the patterned portion.

In an embodiment, the window may further include a lower filling layer filled in the second groove patterns.

In an embodiment, each of the plurality of first groove patterns may have a first length in the second direction, each of the plurality of second groove patterns may have a second length in the second direction, and the first length may be less than the second length.

In an embodiment, a third length of each of the plurality of first areas in the second direction may substantially the same as the first length.

In an embodiment, the plurality of first groove patterns and the plurality of second groove patterns may be arranged alternately with each other in the second direction.

In an embodiment, the patterned portion may include a wall portion defined between a first groove pattern of the plurality of first groove patterns and a second groove pattern of the plurality of second groove patterns, which are adjacent to each other, a lower portion extending from a lower side of the wall portion in the second direction and including the bottom surface of the patterned portion, and an upper portion extending from an upper side of the wall portion in the second direction and including the top surface of the patterned portion.

In an embodiment, the wall portion may correspond to the plurality of first areas.

In an embodiment, the wall portion may correspond to the peripheral area.

In an embodiment of the invention, a display device includes a folding area foldable around a folding axis on a plane, and a non-folding area adjacent to the folding area, and the display device includes a display panel including a light emitting element, and a window disposed on the display panel and including a patterned glass. In such an embodiment, the folding area includes a folding emission area corresponding to the light emitting element, and a folding non-emission area adjacent to the folding emission area, and the patterned glass includes a patterned portion corresponding to the folding area, and having a top surface in which a plurality of first groove patterns are defined, and a bottom surface in which a plurality of second groove patterns are defined, and a non-patterned portion adjacent to the patterned portion and corresponding to the non-folding area. In such an embodiment, the patterned portion includes a wall portion defined between a first groove pattern of the plurality of first groove patterns and a second groove pattern of the plurality of second groove patterns, which are adjacent to each other, a lower portion extending from a lower side of the wall portion in one direction and including the bottom surface of the patterned portion, and an upper portion extending from an upper side of the wall portion in the one direction and including the top surface of the patterned portion. In such an embodiment, the wall portion corresponds to the folding emission area or the folding non-emission area.

In an embodiment, the folding emission area may include a plurality of first areas which emits first light, a plurality of second areas which emits second light, and a plurality of third areas which emits third light.

In an embodiment, the wall portion may correspond to the plurality of second areas or the plurality of third areas, and the lower portion, the upper portion, the plurality of first groove patterns, and the plurality of second groove patterns may correspond to the plurality of first areas.

In an embodiment, the wall portion may correspond to the plurality of first areas, and the lower portion, the upper portion, the plurality of first groove patterns, and the plurality of second groove patterns may correspond to the plurality of second areas or the plurality of third areas.

In an embodiment, the wall portion may correspond to the folding non-emission area, and the lower portion, the upper portion, the plurality of first groove patterns, and the plurality of second groove patterns may correspond to the plurality of first areas, the plurality of second areas, or the plurality of third areas.

In an embodiment, the plurality of first groove patterns may correspond to the plurality of first areas, and the plurality of second groove patterns may correspond to the plurality of second areas or the plurality of third areas.

### BRIEF DESCRIPTION OF THE DRAWINGS

The above and other features of embodiments of the invention will become more apparent by describing in further detail embodiments thereof with reference to the accompanying drawings, in which:

FIG. 1 is a block diagram of an electronic device according to an embodiment of the invention;

FIG. 2 are schematic views of electronic devices according to various embodiments of the invention;

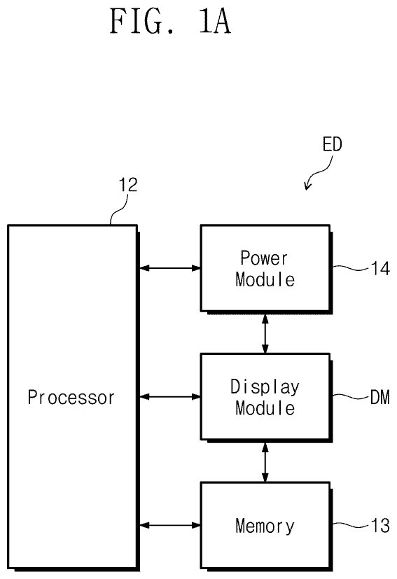

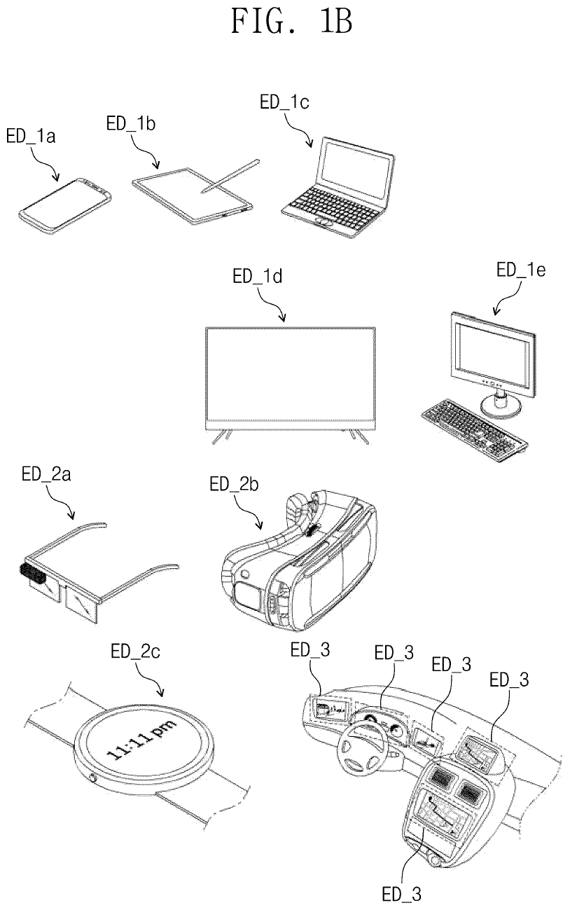

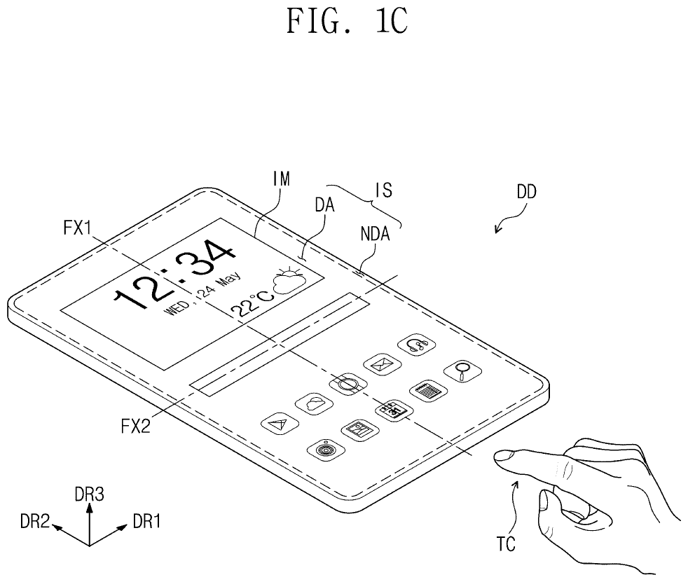

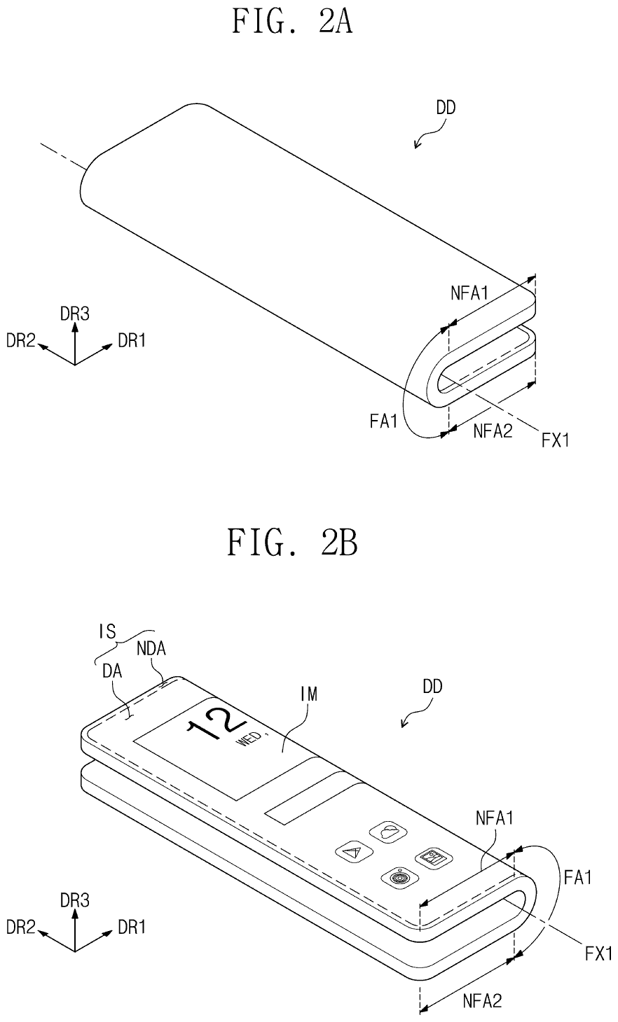

FIG. 1C is a perspective view of a display device according to an embodiment of the invention;

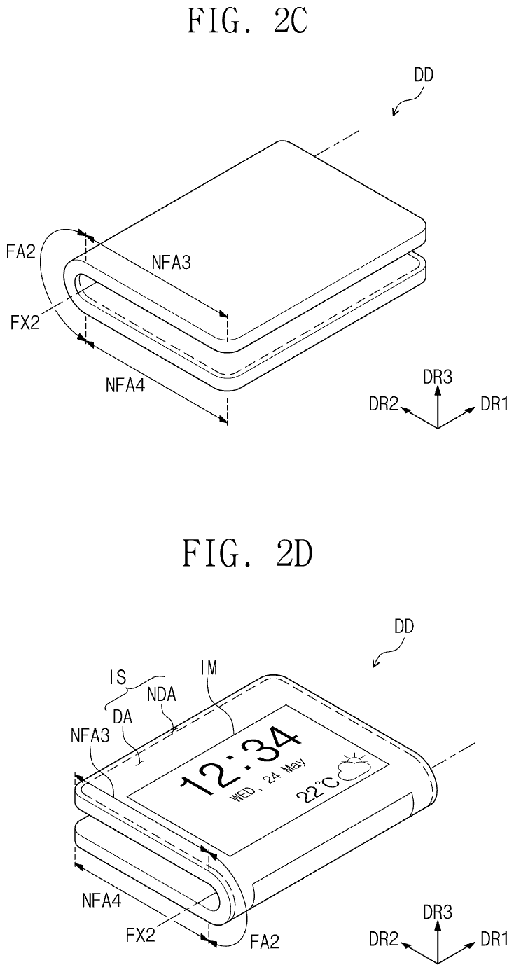

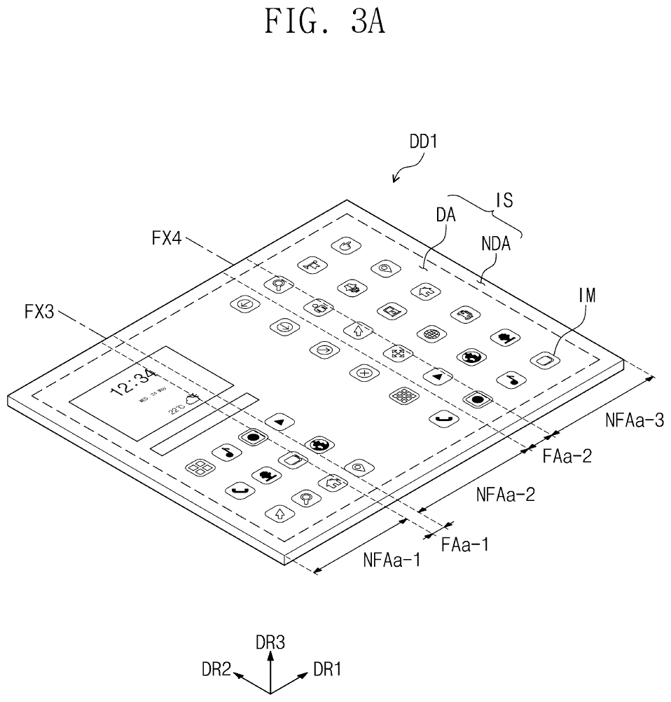

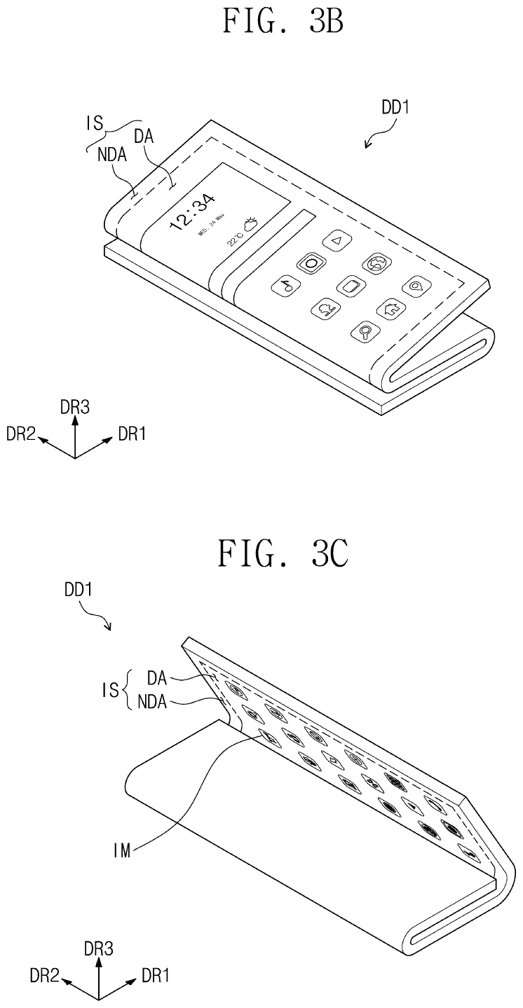

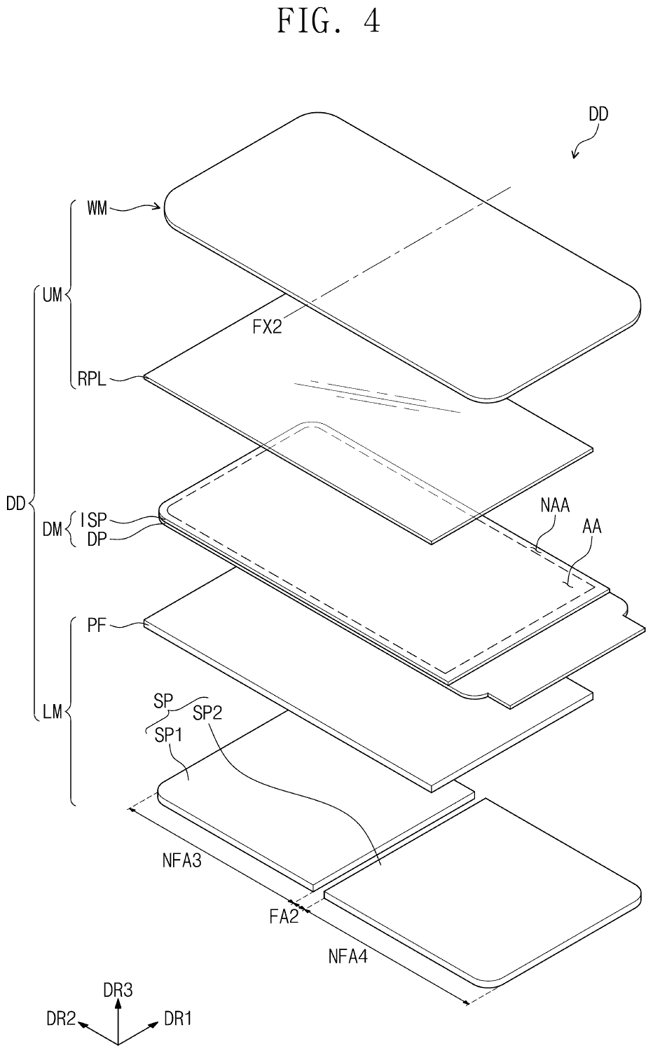

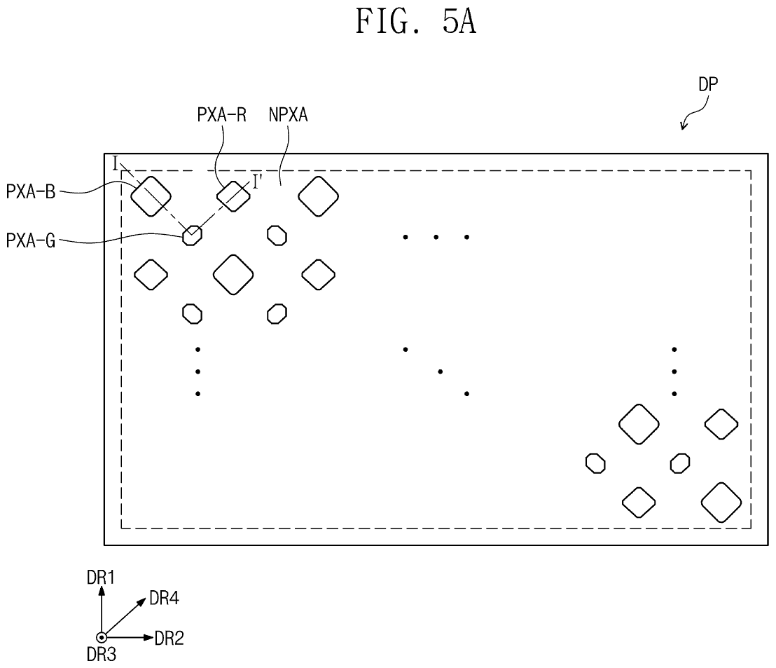

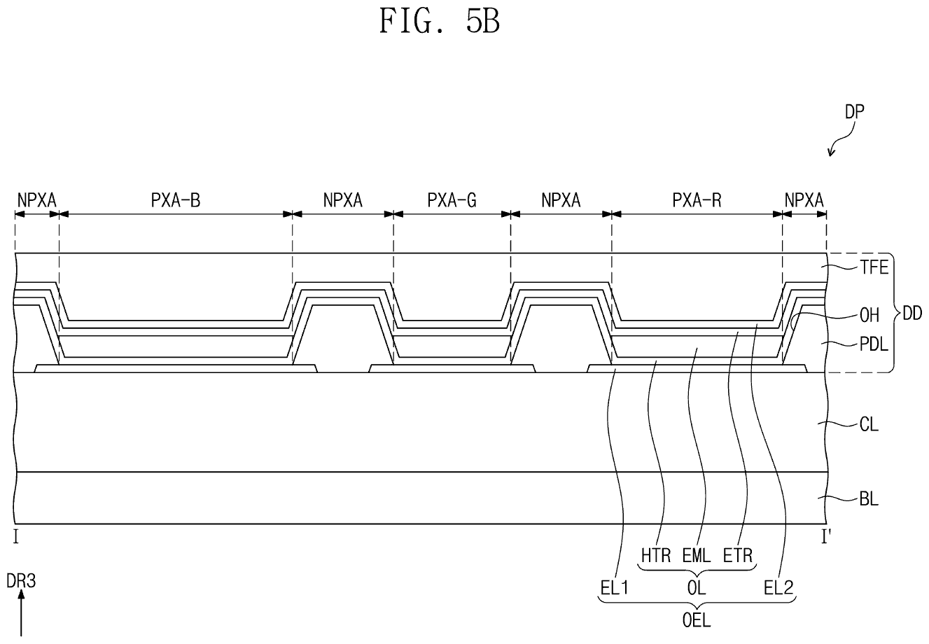

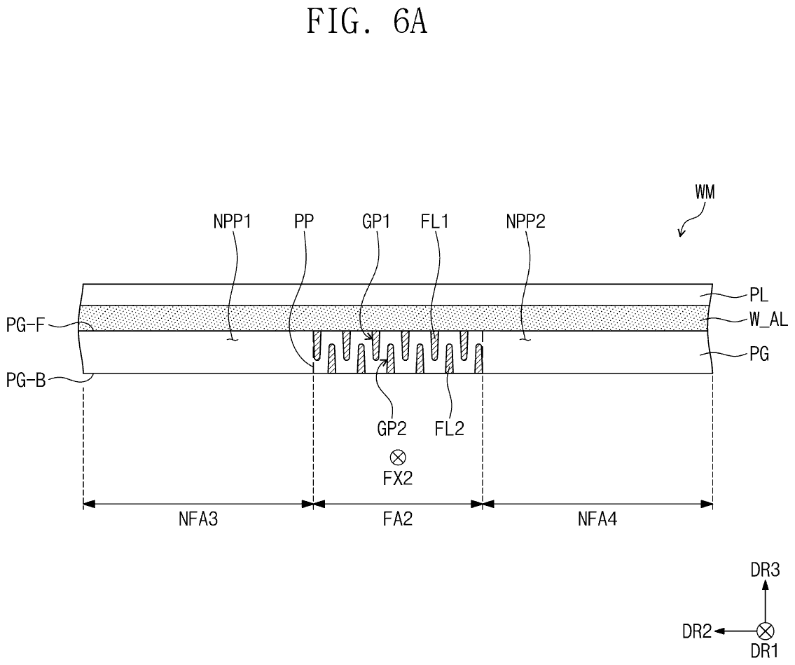

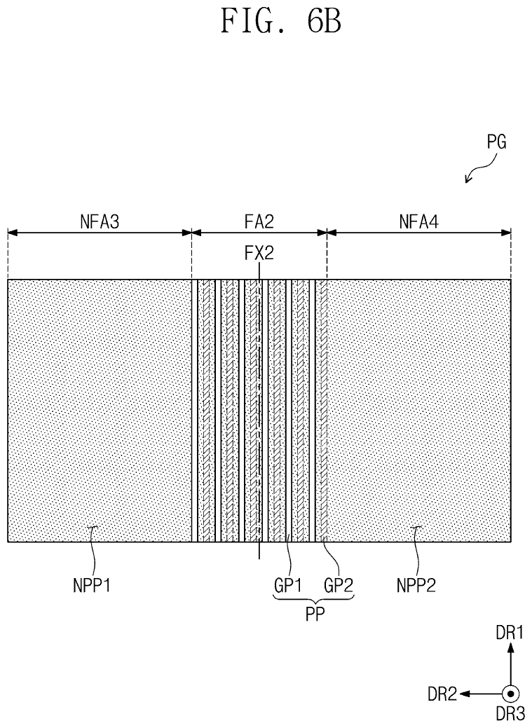

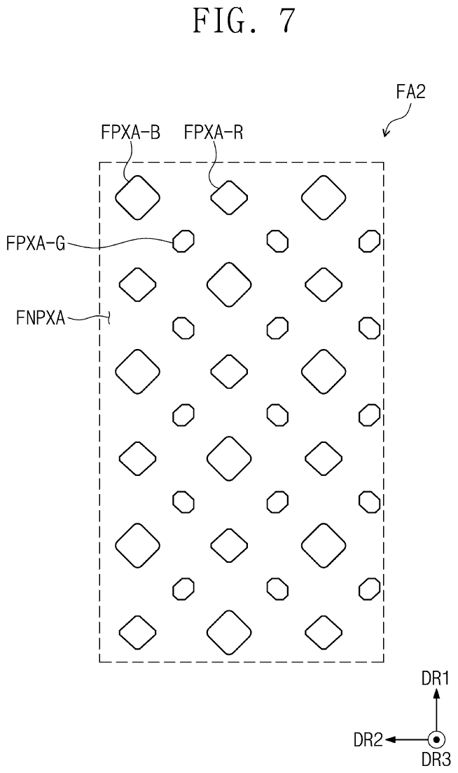

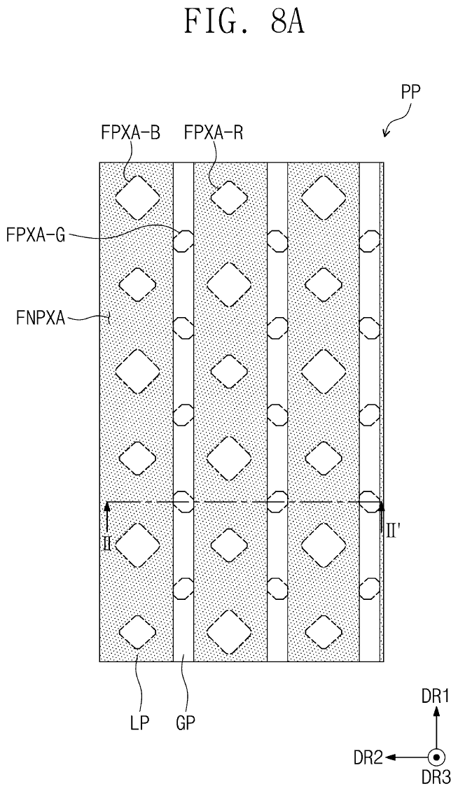

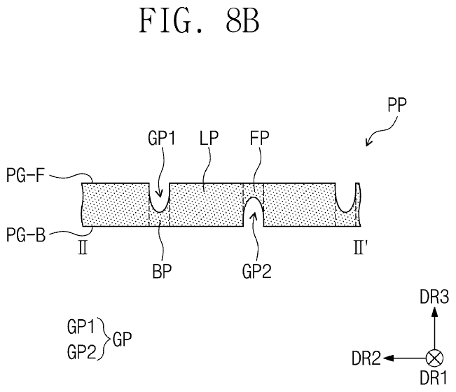

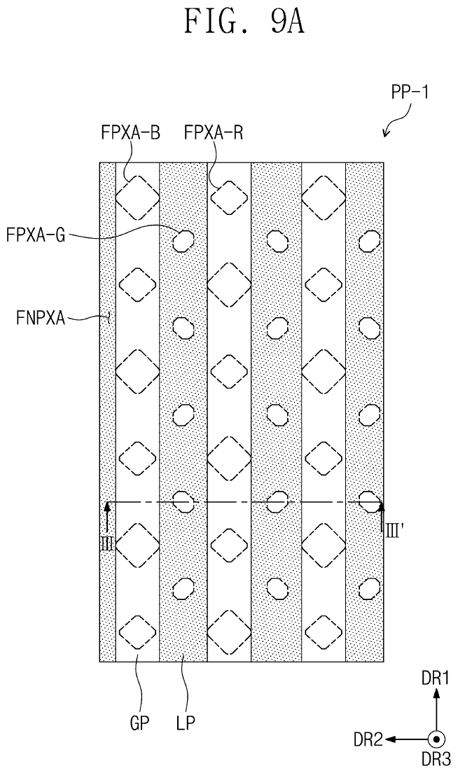

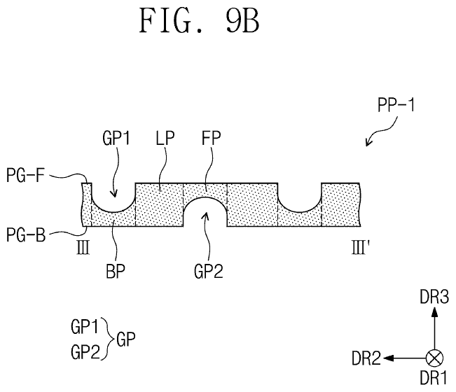

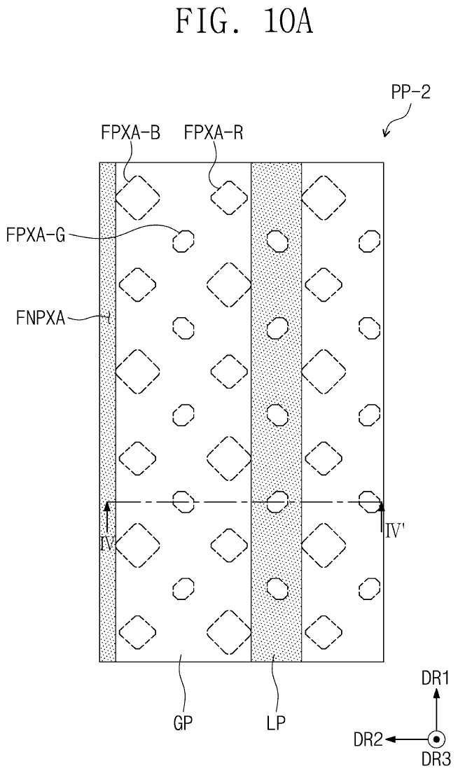

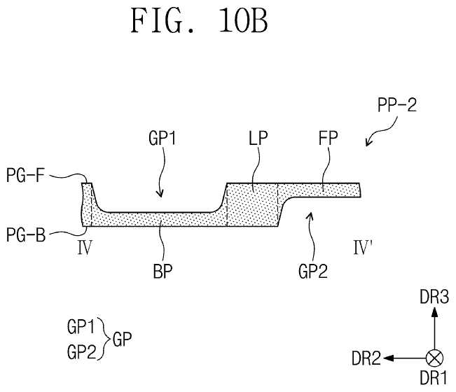

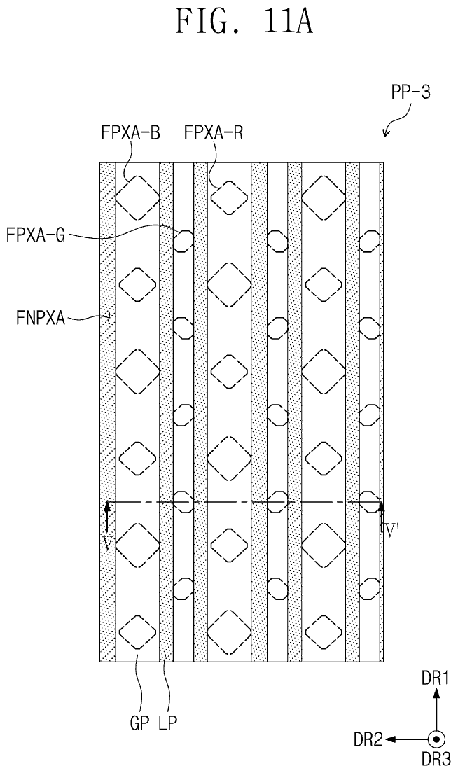

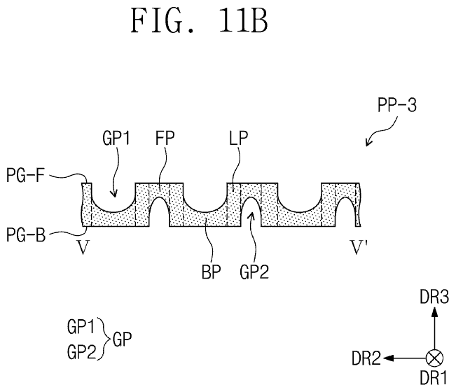

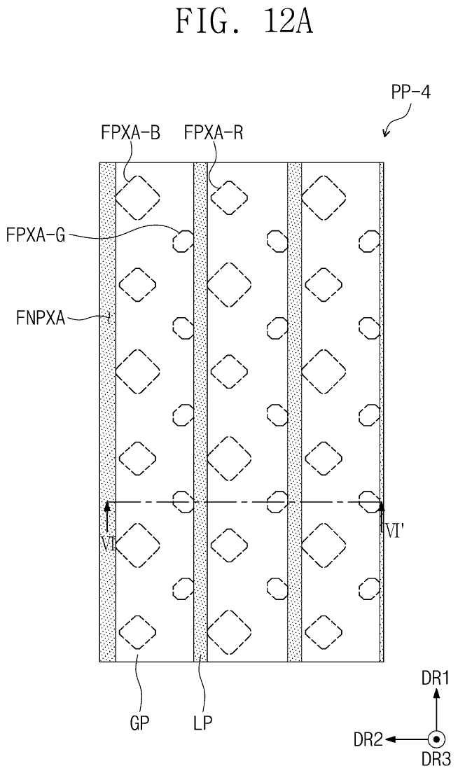

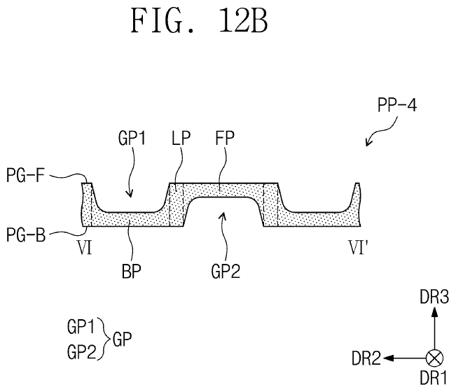

FIGS. 2A to 2D are views illustrating the display device illustrated in FIG. 1C in a state in which the display device is folded;

FIG. 3A is a perspective view of a spread state of a display device according to an embodiment of the invention;

FIGS. 3B and 3C are views illustrating the display device illustrated in FIG. 3A in a state in which the display device is folded;

FIG. 4 is an exploded perspective view of a display device according to an embodiment of the invention;

FIG. 5A is an enlarged plan view illustrating a portion of a display panel included in a display device according to an embodiment of the invention;

FIG. 5B is a cross-sectional view illustrating a portion of a display panel according to an embodiment of the invention;

FIG. 6A is a cross-sectional view illustrating a portion of a cross-section of a window according to an embodiment of the invention;

FIG. 6B is a plan view illustrating a patterned glass according to an embodiment of the invention;

FIG. 7 is a plan view illustrating a portion corresponding to a folding area of a display panel according to an embodiment of the invention;

FIG. 8A is a plan view illustrating a portion corresponding to a folding area of a window according to an embodiment of the invention;

FIG. 8B is a cross-sectional view illustrating a portion corresponding to a folding area of a window according to an embodiment of the invention;

FIGS. 9A, 10A, 11A and 12A are each a plan view illustrating a portion corresponding to a folding area of a window according to an embodiment of the invention; and

FIGS. 9B, 10B, 11B and 12B are each a cross-sectional view illustrating a portion corresponding to a folding area of a window according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the present disclosure, it will be understood that when an element (or region, layer, section, etc.) is referred to as being “on”, “connected to” or “coupled to” another element, it can be disposed directly on, connected or coupled to the other element or a third element may be disposed between the elements.

Like reference numbers or symbols refer to like elements throughout. In addition, in the drawings, the thickness, the ratio, and the dimension of elements are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

FIG. 1A is a block diagram of an electronic device according to an embodiment. Referring to FIG. 1A, an electronic device ED according to an embodiment may include a display module DM, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information required for the operation of the processor 12 or the display module DM. When the processor 12 executes an application stored in the memory 15, image data signals and/or input control signals are transmitted to the display module DM, and the display module DM may process the received signal and output image information through a display screen.

The power module 14 may include a power supply module such as a power adapter or a battery device, and a power conversion module that converts power supplied by the power supply module to generate power required for the operation of the electronic device ED.

At least one of the components of the electronic device ED described above may be included in the display device according to the above-described embodiments. In addition, some of the individual modules functionally included in one module may be included in the display device, and others may be separately provided from the display device. For example, the display device may include a display module DM, and the processor 12, the memory 13, and the power module 14 may be provided in the form of other devices within the electronic device ED, rather than the display device.

FIG. 1B shows schematic views of electronic devices according to various embodiments.

Referring to FIG. 1B, various electronic devices to which the display device according to embodiments is applied may include an electronic device for displaying images, such as a smart phone ED_1a, a tablet PC ED_1b, a laptop ED_1c, a TV ED_1d, and a desk monitor ED_1e, a wearable electronic device including a display module such as a smart glasses ED_2a, a head mounted display ED_2b, and a smart watch ED_2c, and a vehicle electronic device ED_3 including a display module such as a center information display (CID) and a room mirror display disposed on an instrument panel, a center fascia, or a dashboard of a vehicle. In addition, these devices are merely provided as embodiments, and other electronic devices may be employed as long as not departing from the inventive concept.

FIG. 1C is a perspective view of a display device according to an embodiment of the invention.

Referring to FIG. 1C, an embodiment of a display device DD may be a device that is activated in response to an electrical signal. The display device DD may include various embodiments. For example, the display device DD may be used in large-sized electronic devices such as televisions, monitors, or outdoor billboards, and also in small and medium-sized electronic devices such as personal computers, notebook computers, personal digital assistants, vehicle navigation units, game consoles, portable electronic devices, and cameras. In FIG. 1C, an embodiment where the display device DD is implemented as a smartphone is illustrated as an example.

In an embodiment, the display device DD has a rectangular shape having short sides in a first direction DR1 and having long sides in a second direction DR2 crossing the first direction DR1 when viewed in a plan view or when viewed in a third direction DR3. Here, the third direction DR3 may be a direction perpendicular to a plane defined by the first direction DR1 and the second direction DR2 or a thickness direction of the display device DD. However, the shape of the display device DD is not limited thereto, and the display device DD having various planar shapes may be provided.

The display device DD may be a foldable display device. In an embodiment, for example, the display device DD may be folded or foldable around a folding axis extending in a predetermined direction. Hereinafter, a state in which a component is flat without being folded is defined as a first state (i.e., a non-folded state), and a state in which the component is folded around the folding axis is defined as a second state (i.e., a folded state). The folding axis is an imaginary rotary axis generated when the display device DD is folded, and may be defined by a mechanical structure of the display device DD.

The folding axis may extend in the first direction DR1 or the second direction DR2. In an embodiment of the invention, the folding axis extending in the second direction DR2 is defined as a first folding axis FX1, and the folding axis extending in the first direction DR1 is defined as a second folding axis FX2. The display device DD may include any one folding axis of the first and second folding axes FX1 and FX2. That is, the display device DD may be folded or foldable around one of the first and second folding axes FX1 and FX2.

In an embodiment, as illustrated in FIG. 1C, the display device DD may display an image IM on a display surface IS parallel to each of the first direction DR1 and the second direction DR2. The display surface IS on which the image IM is displayed may correspond to a front surface of the display device DD. A direction perpendicular to the display surface IS, i.e., the thickness direction of the display device DD, may be referred to as the third direction DR3. The display device DD may display the image IM in the third direction DR3.

The display surface IS of the display device DD may be divided into a plurality of areas. A display area DA and a non-display area NDA may be defined in the display surface IS of the display device DD.

The display area DA may be an area on which an image IM is displayed, and the image IM is visible to a user through the display area DA. The display device DA may have a rectangular shape. The non-display area NDA is an area which is adjacent to the display area DA and on which the image IM is not be displayed. A bezel area of the display device DD may be defined by the non-display area NDA. In an embodiment of the invention, the non-display area NDA may surround the display area DA. Accordingly, the shape of the display area DA may be substantially defined by the non-display area NDA. However, this is illustrated as an example. In another embodiment, the non-display area NDA may be disposed adjacent to only one side of the display area DA, or the non-display area NDA may be omitted.

The display device DD according to an embodiment of the invention may sense a user's input TC applied from the outside. The user's input TC includes various types of external inputs such as a part of a user's body, light, heat, or pressure. In this embodiment, the user's input TC is illustrated as the user's hand applied to the front surface. However, this is illustrated as an example. As described above, the user's input TC may be provided in various shapes, and the display device DD may sense the user's input TC applied to a side surface or a rear surface of the display device DD according to a structure of the display device DD, but is not limited to any one embodiment.

The display device DD may activate the display surface IS to display the image IM, and also sense the user's input TC. In an embodiment, an area which senses the user's input TC may be provided on the display area DA on which the image IM is displayed. However, this is illustrated as an example, and the area which senses the user's input TC may be provided on the non-display area NDA or provided on an entire area of the display surface IS.

FIGS. 2A to 2D are views illustrating the display device illustrated in FIG. 1C in a state in which the display device is folded.

FIG. 2A is a view illustrating the display device DD in a state in which the display device DD is in-folded along a first folding axis FX1. FIG. 2B is a view illustrating the display device DD in a state in which the display device DD is out-folded along the first folding axis FX1.

FIG. 2C is a view illustrating the display device DD in a state in which the display device DD is in-folded along a second folding axis FX2. FIG. 2D is a view illustrating the display device DD in a state in which the display device DD is out-folded along the second folding axis FX2.

Referring to FIGS. 2A to 2D, an embodiment of the display device DD may be a foldable display device. The display device DD may be folded or foldable around a folding axis extending in a predetermined direction, for example, the first folding axis FX1 or the second folding axis FX2).

Referring to FIGS. 2A and 2B, according to an operation type, a plurality of areas may be defined in the display device DD. The plurality of areas may be divided into a folding area FA1 and one or more non-folding areas NFA1 and NFA2. The folding area FA1 is defined between two non-folding areas NFA1 and NFA2.

The folding area FA1 is an area folded or foldable around the first folding axis FX1, and an area that substantially forms a curvature. Here, the first folding axis FX1 may extend in the second direction DR2, i.e., a long-axis direction of the display device DD. The folding area FA1 is defined as an area folded or foldable along the first folding axis FX1 and extending in the second direction DR2.

In an embodiment of the invention, the non-folding areas NFA1 and NFA2 may include a first non-folding area NFA1 and a second non-folding area NFA2. The first non-folding area NFA1 is adjacent to one side of the folding area FA1 in the first direction DR1, and the second non-folding area NFA2 is adjacent to the other side of the folding area FA in the first direction DR1.

The display device DD may be in-folded or out-folded. A folding operation, in which respective display surfaces of the different non-folding areas NFA1 and NFA2 are folded to face each other, is defined as an in-folding operation, and a folding operation in which the display surfaces of the different non-folding areas NFA1 and NFA2 are folded to face the outside is defined as an out-folding operation.

Here, the in-folding operation refers to a folding operation in which portions of the display surface IS are folded to face each other, and the out-folding operation refers to a folding operation in which portions of the rear surface of the display device DD are folded to face each other.

In an embodiment, as illustrated in FIG. 2A, the display device DD may be in-folded so that the display surface IS (see FIG. 1C) of the first non-folding area NFA1 and the display surface IS (see FIG. 1C) of the second non-folding area NFA2 face each other. The first non-folding area NFA1 may rotate around the first folding axis FX1 clockwise so that the display device DD is in-folded. In an embodiment where the display device DD1 is in-folded in a way such that the first non-folding area NFA1 and the second non-folding area NFA2 are aligned, the first folding axis FX1 may be defined at a center of the display device DD in the first direction DR1.

Referring to FIG. 2B, an embodiment of the display device DD may be out-folded around the first folding axis FX1. The display device DD may display the image IM when the display surface of the first non-folding area NFA1 and the display surface of the second non-folding area NFA2 are exposed to the outside. In addition, the display surface of the folding area FA1 exposed to the outside may also display the image IM. As illustrated in FIG. 1C, the display device DD may display the image IM in a spread (or fully unfolded) state. The first non-folding area NFA1, the second non-folding area NFA2, and the folding area FA1 may display images, which provide pieces of information independent of each other, respectively, or may display portions of one image, which provides one piece of information, respectively.

The display device DD may be manufactured to have both the in-folded state and the out-folded state, or may be manufactured to have any one of the in-folded state and the out-folded state.

Referring to FIGS. 2C and 2D, an embodiment of the display device DD may be in-folded or out-folded around the second folding axis FX2. The second folding axis FX2 may extend in the first direction DR1, i.e., a short-axis direction of the display device DD.

According to an operation type, a plurality of areas may be defined in the display device DD. The plurality of areas may be divided into a folding area FA2 and one or more non-folding areas NFA3 and NFA4. The folding area FA2 is defined between two non-folding areas NFA3 and NFA4.

The folding area FA2 is an area folded or foldable around the second folding axis FX2, and an area that substantially forms a curvature. The folding area FA2 is defined as an area folded or foldable along the second folding axis FX2 and extending in the first direction DR1.

In an embodiment of the invention, the non-folding areas NFA3 and NFA4 may include a first non-folding area NFA3 and a second non-folding area NFA4. The first non-folding area NFA3 is adjacent to one side of the folding area FA2 in the second direction DR2, and the second non-folding area NFA4 is adjacent to the other side of the folding area FA2 in the second direction DR2.

FIG. 3A is a perspective view of a spread state of a display device according to an embodiment of the invention. FIGS. 3B and 3C are views illustrating the display device illustrated in FIG. 3A in a state in which the display device is multi-folded.

Referring to FIGS. 3A to 3C, an embodiment of a display device DD1 may be a multi-foldable display device. A plurality of folding areas may be defined in the display device DD1. The display device DD1 may include a plurality of folding areas FAa-1 and FAa-2 and a plurality of non-folding areas NFAa-1, NFAa-2 and NFAa-3. In an embodiment of the invention, the display device DD1 may include a first folding area FAa-1, a second folding area FAa-2, a first non-folding area NFAa-1, a second non-folding area NFAa-2, and a third non-folding area NFAa-3. In the first direction DR1, the first folding area FAa-1 is disposed between the first non-folding area NFAa-1 and the second non-folding area NFAa-2, and the second folding area FAa-2 is disposed between the second non-folding area NFAa-2 and the third non-folding area NFAa-3. Although an embodiment where two folding areas FAa-1 and FAa-2 and three non-folding areas NFAa-1, NFAa-2 and NFAa-3 are defined is illustrated as an example, the number of the folding areas FAa-1 and FAa-2 and the number of the non-folding areas NFAa-1, NFAa-2 and NFAa-3 are not limited thereto, and may increase.

Referring to FIGS. 3A and 3B, the first folding area FAa-1 may be folded around a third folding axis FX3 parallel to the second direction DR2. The first folding area FAa-1 may be inner-folded so that a display surface of the second non-folding area NFAa-2 and a display surface of the first non-folding area NFAa-1 face each other. The second folding area FAa-2 may be folded around a fourth folding axis FX4 parallel to the second direction DR2. The second folding area FAa-2 may be outer-folded so that a rear surface of the second non-folding area NFAa-2 and a rear surface of the third non-folding area NFAa-3 face each other, and a display surface of the third non-folding area NFAa-3 faces the outside.

Referring to FIGS. 3A and 3C, the first folding area FAa-1 may be folded around the third folding axis FX3 parallel to the second direction DR2. The first folding area FAa-1 may be inner-folded so that the display surface of the first non-folding area NFAa-1 is disposed in the inside, and the display surface of the second non-folding area NFAa-2 and the display surface of the first non-folding area NFAa-1 face each other. The second folding area FAa-2 may be folded around the fourth folding axis FX4 parallel to the second direction DR2. The second folding area FAa-2 may be inner-folded so that a rear surface of the first non-folding area NFAa-1 and the display surface of the third non-folding area NFAa-3 face each other.

In an embodiment of the invention, the outer-folding operation and the inner-folding operation may be performed at the same time, and only one of the outer-folding operation and the inner-folding operation may be performed.

Although FIGS. 3B and 3C illustrate an embodiment of the display device DD1 in the multi-folded states, an embodiment of the invention is not limited thereto, and the display device DD1 may have various folding shapes.

FIG. 4 is an exploded perspective view of a display device according to an embodiment of the invention.

Referring to FIG. 4, a display device DD according to an embodiment may include a display module DM which displays an image, an upper module UM disposed on the display module DM, and a lower module LM disposed below the display module DM. The display module DM may constitute a part of the display device DD. In an embodiment, the image may be generated by the display module DM.

The display module DM may include a display panel DP and an input sensing unit ISP. The display panel DP according to an embodiment of the invention may be an emissive display panel, and is not particularly limited. In an embodiment, for example, the display panel DP may be an organic light emitting display panel, an inorganic light emitting display panel or a quantum-dot light emitting display panel. An emission layer of the organic light emitting display panel may include an organic light emitting material, and an emission layer of the inorganic light emitting display panel may include an inorganic light emitting material. An emission layer of the quantum-dot light emitting display panel may include a quantum dot, a quantum rod, and the like. Hereinafter, for convenience of description, embodiments where the display panel DP is the organic light emitting display panel will be described in detail as an example.

The display panel DP may be a foldable display panel. Accordingly, the display panel DP may be rolled as a whole, or may be folded or unfolded about a folding axis FX2.

The input sensing unit ISP may be disposed directly on the display panel DP. According to an embodiment of the invention, the input sensing unit ISP may be formed on the display panel DP through a continuous process. That is, when the input sensing unit ISP is disposed directly on the display panel DP, an adhesive film is not disposed between the input sensing unit ISP and the display panel DP. However, an embodiment of the invention is not limited thereto. In another embodiment, for example, an adhesive film may be disposed between the input sensing unit ISP and the display panel DP. In such an embodiment, the input sensing unit ISP is not manufactured together with the display panel DP through a continuous process, and the input sensing unit ISP may be manufactured through a separate process from the display panel DP, and then fixed or attached to a top surface of the display panel DP through an adhesive film.

The display panel DP generates an image, and the input sensing unit ISP obtains coordinate information of a user's input (e.g., touch event).

The upper member UM may include a window WM disposed on the display module DM. The window WM may include an optically transparent insulation material. Accordingly, the image generated by the display module DM may pass through the window WM and be easily perceived by the user.

The window WM may be folded or unfolded about the folding axis FX2. That is, when a shape of the display module DM is changed, a shape of the window WM may be changed together. The window WM transmits the image from the display module DM and also reduces an external impact to prevent the display module DM from being damaged or malfunctioning due to the external impact. The impact from the outside is a force from the outside which may be expressed as pressure or stress, and means a force that causes a defect to occur in the display module DM.

The upper module UM may further include at least one functional layer disposed between the display module DM and the window WM. In an embodiment of the invention, the functional layer may be an anti-reflective layer RPL that blocks reflection of external light.

The anti-reflective layer RPL may effectively prevent elements constituting the display module DM from being visible from the outside due to external light incident through a front surface of the display device DD. The anti-reflective layer RPL may include a retarder and a polarizer. The retarder may be a film type or a liquid crystal coating type, and may include a λ/2 retarder and/or a λ/4 retarder. The polarizer may also be a film type or a liquid crystal coating type. The film type may include a stretchable synthetic resin film, and the liquid crystal coating type may include liquid crystals arranged in a predetermined arrangement. The retarder and the polarizer may be provided as a single polarizing film. The functional layer may further include a protective film disposed above or below the anti-reflective layer RPL.

The upper module UM may further include a first adhesive film provided between the anti-reflective layer RPL and the display module DM. The first adhesive film may include an optically transparent adhesive material. In an embodiment of the invention, the first adhesive film may include a pressure sensitive adhesive (PSA), an optical clear adhesive (OCA), or an optical clear resin (OCR).

The display module DM may display an image in response to an electrical signal, and transmit/receive information of an external input. The display module DM may include an active area AA and a peripheral area NAA. The active area AA may be defined as an area from which an image provided by the display module DM is emitted.

The peripheral area NAA is adjacent to the active area AA. In an embodiment, for example, the peripheral area NAA may surround the active area AA in a plan view or when viewed in the third direction DR3. However, this is illustrated as an example, and the peripheral area NAA may be defined to have various shapes, and is not limited to any one embodiment. According to an embodiment, the active area AA of the display module DM may correspond to at least a portion of the display area DA (see FIG. 1C).

The lower module LM includes a support plate SP that is disposed on a rear surface of the display module DM and supports the display module DM. The support plate SP may include a plurality of support plates to correspond to the number of non-folding areas NFA3 and NFA4. In an embodiment of the invention, the support plate SP may include a first support plate SP1, and a second support plate SP2 disposed apart from the first support plate SP1.

The first and second support plates SP1 and SP2 may be disposed to correspond to first and second non-folding areas NFA3 and NFA4, respectively. The first support plate SP1 is disposed to correspond to the first non-folding area NFA3 of the display module DM, and the second support plate SP2 is disposed to correspond to the second non-folding area NFA4 of the display module DM. Each of the first and second support plates SP1 and SP2 may include a metal material or a plastic material.

When the display module DM is in a first state of being flat, the first and second support plates SP1 and SP2 are disposed apart from each other in the second direction DR2. When the display module DM is in a second state of being folded around the folding axis FX2, the first and second support plates SP1 and SP2 may be disposed apart from each other in the third direction DR3.

The first and second support plates SP1 and SP2 may be spaced apart from each other in an area corresponding to the folding area FA2. Each of the first and second support plates SP1 and SP2 may partially overlap the folding area FA2. That is, in the second direction DR2, a separation distance between the first and second support plates SP1 and SP2 may be less than a width of the folding area FA2.

The support plate SP may further include a connecting module for connecting the first and second support plates SP1 and SP2 to each other. The connecting module may include a hinge module or a multi-joint module.

Although an embodiment in which the support plate SP includes two support plates SP1 and SP2 is illustrated, an embodiment of the invention is not limited thereto. That is, in an embodiment where the folding axis FX2 is provided in plurality, the support plate SP may include a plurality of support plates separated on the basis of a plurality of folding axes FX2. Alternatively, the support plate SP may be provided in the form of one body without being separated into the first and second support plates SP1 and SP2. In such an embodiment, the support plate SP may be provided with a bending part corresponding to the folding area FA2. The bending part may be provided with an opening defined through the support plate SP, or provided with a groove recessed from one surface of the support plate SP.

The lower module LM further includes a protective film PF disposed between the display module DM and the support plate SP. The protective film PF may be a layer that is disposed below the display module DM and protects a rear surface of the display module DM. The protective film PF may include a synthetic resin film, and may be, for example, a polyimide film or a polyethylene terephthalate film. However, this is illustrative, and the protective film PF is not limited to the foregoing examples.

FIG. 5A is an enlarged plan view illustrating a portion of a display panel included in a display device according to an embodiment of the invention. FIG. 5B is a cross-sectional view illustrating a portion of a display panel according to an embodiment of the invention. FIG. 5B is a cross-sectional view taken along line I-I′ in FIG. 5A.

Referring to FIGS. 5A and 5B, an embodiment of a display panel DP may include a non-emission area (or non-emission region) NPXA and emission areas (or emission regions) PXA-R, PXA-G and PXA-B. The emission areas PXA-R, PXA-G and PXA-B may be areas from which light generated from light emitting elements OEL is emitted. The emission areas PXA-R, PXA-G and PXA-B may have different surface areas, and here, the surface areas may indicate surface areas when viewed on a plane or in a plan view.

The emission areas PXA-R, PXA-G and PXA-B may be divided into a plurality of groups according to colors of the light generated from the light emitting elements OEL. In the display panel DP according to an embodiment illustrated in FIGS. 5A and 5B, three emission areas PXA-R, PXA-G and PXA-B that emit red light, green light, and blue light, respectively, are illustrated as an example.

The emission areas PXA-R, PXA-G and PXA-B may have different surface areas according to colors of light emitted from an emission layer EML of each of the light emitting elements OEL. For example, referring to FIG. 5A, in the display panel DP according to an embodiment, a blue emission area PXA-B of each of light emitting elements which emit blue light may have the largest surface, and a green emission area PXA-G of each of light emitting elements which generate green light may have the smallest surface area. However, an embodiment is not limited thereto, and the emission areas PXA-R, PXA-G and PXA-B may emit light of colors other than the red light, the green light, and the blue light, the emission areas PXA-R, PXA-G and PXA-B may the same surface area as each other, or the emission areas PXA-R, PXA-G and PXA-B may be provided in a different surface area ratio from those illustrated in FIGS. 5A and 5B.

The emission areas PXA-R, PXA-G and PXA-B may be areas divided (or defined) by a pixel defining film PDL. The non-emission area NPXA is an area between neighboring emission areas PXA-R, PXA-G and PXA-B, and may be an area correspond to the pixel defining film PDL. In the disclosure, each of the emission areas PXA-R, PXA-G and PXA-B may correspond to an area of a pixel.

The pixel defining film PDL may include or be made of polymer resin. In an embodiment, for example, the pixel defining film PDL may include polyacrylate-based resin or polyimide-based resin. The pixel defining film PDL may further include an inorganic material in addition to polymer resin. The pixel defining film PDL may include a light absorbing material, or may include a black pigment or a black dye. The pixel defining film PDL including the black pigment or the black dye may achieve a black pixel defining film. When forming the pixel defining film PDL, a carbon black or the like may be used as the black pigment or the black dye, but an embodiment is not limited thereto.

The pixel defining film PDL may include or be made of an inorganic material. In an embodiment, for example, the pixel defining film PDL may include silicon nitride (SiNₓ), silicon oxide (SiOₓ), silicon oxynitride (SiOₓN_{y}), or the like. The pixel defining film PDL may define the emission areas PXA-R, PXA-G and PXA-B. The emission areas PXA-R, PXA-G and PXA-B and the non-emission area NPXA may be divided by the pixel defining film PDL.

The green emission areas PXA-G may be arranged in the second direction DR2 to constitute a first pixel row. The blue emission areas PXA-B and red emission areas PXA-R may be alternately disposed along the second direction DR2 to constitute a second pixel row. The first pixel row may be disposed apart from the second pixel row in the first direction DR1. Each of the first pixel row and the second pixel row may be provided in plurality. The first pixel rows and the second pixel rows may be arranged to alternate with each other along the first direction DR1.

One green emission area PXA-G may be disposed apart from one blue emission area PXA-B or one red emission area PXA-R in a fourth direction DR4. The fourth direction DR4 may be a direction between the first direction DR1 and the second direction DR2.

An arrangement structure of the emission areas PXA-R, PXA-G and PXA-B illustrated in FIG. 5A may be referred to as a PenTile® structure. However, the arrangement structure of the emission areas PXA-R, PXA-G and PXA-B in the display panel DP according to an embodiment is not limited to the arrangement structure illustrated in FIG. 5A. For example, in an embodiment, the emission areas PXA-R, PXA-G and PXA-B may have a stripe structure in which the red emission area PXA-R, the green emission area PXA-G, and the blue emission area PXA-B are alternately arranged in sequence along the first direction DR1, or be in a PenTile® array.

In an embodiment, the light emitting element OEL may include a first electrode EL1 and a second electrode EL2 which face each other, and a plurality of organic layers OL disposed between the first electrode EL1 and the second electrode EL2. The organic layers OL may include a hole transport region HTR, the emission layer EML, and an electron transport region ETR.

The light emitting element OEL may include the first electrode EL1, the hole transport region HTR disposed on the first electrode EL1, the emission layer EML disposed on the hole transport region HTR, the electron transport region ETR disposed on the emission layer EML, and the second electrode EL2 disposed on the electron transport region ETR.

FIG. 5B illustrates an embodiment in which the emission layer EML of the light emitting element OEL is disposed in an opening portion OH defined in the pixel defining film PDL. However, an embodiment is not limited thereto. In another embodiment, the emission layer EML may be provided as a common layer to all the light emitting elements OEL. The light emitting elements OEL may emit light in a same wavelength region, or at least one thereof may emit light in a different wavelength region. In an embodiment, for example, all the light emitting elements OEL may emit the blue light.

An encapsulation member TFE which protects the light emitting element OEL may be disposed on the light emitting element OEL, and the encapsulation member TFE may be disposed on the second electrode EL2. The encapsulation member TFE may be disposed directly on the second electrode EL2. The encapsulation member TFE may have a single-layer structure or a structure in which a plurality of layers are stacked. The encapsulation member TFE may be a thin film encapsulation layer.

Hereinafter, a window WM according to an embodiment of the invention will be described in detail with reference to the accompanying drawings.

FIG. 6A is a cross-sectional view illustrating a portion of a cross-section of a window according to an embodiment of the invention. FIG. 6B is a plan view illustrating a patterned glass according to an embodiment of the invention.

Referring to FIGS. 6A and 6B, an embodiment of the window WM may include a patterned glass PG, a filling layer FL1, a lower filling layer FL2, a window adhesive layer W_AL, and a window protective layer PL.

The patterned glass PG may include a glass material. The patterned glass PG may include a patterned portion PP and non-patterned portions NPP1 and NPP2. The patterned portion PP may be a portion corresponding to a folding area FA2, and the non-patterned portions NPP1 and NPP2 may be portions corresponding to first and second non-folding areas NFA3 and NFA4. The non-patterned portions NPP1 and NPP2 may include a first non-patterned portion NPP1 corresponding to a first non-folding area NFA3 and a second non-patterned portion NPP2 corresponding to a second non-folding area NFA4. The patterned portion PP may be disposed between the first and second non-patterned portions NPP1 and NPP2.

The patterned glass PG may include a top surface PG-F and a bottom surface PG-B. The top surface PG-F and the bottom surface PG-B indicate two opposing surfaces, which are opposite to each other in a thickness direction thereof, of the patterned glass PG, and may be, for example, two surfaces opposite to each other in the third direction DR3. In the patterned glass PG, in the third direction DR3, a surface adjacent to or facing the anti-reflective layer RPL (see FIG. 4) or the display module DM (see FIG. 4) may be the bottom surface PG-B, and a surface adjacent to or facing the window protective layer PL may be the top surface PG-F.

The patterned part PP may include a plurality of groove patterns GP1 and GP2. In an embodiment, the plurality of groove patterns GP1 and GP2 may include a plurality of first groove patterns GP1 provided (or defined) in the top surface PG-F of the patterned glass PG, and a plurality of second groove patterns GP2 provided in the bottom surface PG-B of the patterned glass PG. Each of the first groove patterns GP1 may have a shape recessed from the top surface PG-F of the patterned glass PG toward the bottom surface PG-B of the patterned glass PG, and each of the second groove patterns GP2 may have a shape recessed from the bottom surface PG-B of the patterned glass PG toward the top surface PG-F of the patterned glass PG.

In an embodiment of the invention, where the folding axis FX2 extends in the first direction DR1, the first groove patterns GP1 may be arranged to be spaced apart from each other in the second direction DR2, and the second groove patterns GP2 may be arranged to be spaced apart from each other in the second direction DR2. Alternatively, in an embodiment where the folding axis FX2 extends in the second direction DR2, the first groove patterns GP1 may be arranged to be spaced apart from each other in the first direction DR1, and the second groove patterns GP2 may be arranged to be spaced apart from each other in the first direction DR1.

Alternatively, each of the groove patterns GP may include a plurality of first sub-groove patterns arranged apart from each other in the first direction DR1. Each of the first sub-groove patterns may have a stripe shape extending in the first direction DR1. The planar shapes of the groove patterns GP are not limited to stripe or linear shapes, and may include various shapes such as polygons as desired.

The filling layer FL1 may fill the first groove patterns GP1, and the lower filling layer FL2 may fill the second groove patterns GP2. In other words, recessed spaces defined by the first groove patterns GP1 may be filled by the filling layer FL, and recessed spaces defined by the second groove patterns GP2 may be filled by the lower filling layer FL2. In an embodiment of the invention, the filling layer FL1 and the lower filling layer FL2 may be provided in only the patterned portion PP, but not be provided in the first and second non-patterned portions NPP1 and NPP2.

Each of the filling layer FL1 and the lower filling layer FL2 may include an organic material. In an embodiment of the invention, the organic material included in each of the filling layer FL1 and the lower filling layer FL2 may include at least one selected from urethane-based resin, epoxy-based resin, polyimide-based resin, polyester-based resin, polyether-based resin, acrylate-based resin, or acrylonitrile-butadiene-styrene (ABS) resin, and rubber. In an embodiment, for example, the organic material included in each of the filling layer FL1 and the lower filling layer FL2 may include at least one selected from phenylene, polyethyleneterephthalate (PET), polyimide (PI), polyamide (PAI), polyethylenenaphthalate (PEN), or polycarbonate (PC).

The window WM may further include the window protective layer PL. The window protective layer PL may be provided or disposed on the patterned glass PG. The window protective layer PL may be provided on the filling layer FL1. The window protective layer PL may function to protect the patterned glass PG from an external impact. The window protective layer PL may include a synthetic resin material. In an embodiment of the invention, the window protective layer PL may include at least one selected from urethane-based resin, epoxy-based resin, polyester-based resin, polyether-based resin, acrylate-based resin, acrylonitrile-butadiene-styrene resin (ABS) resin, and rubber. In an embodiment, for example, the window protective layer PL may include at least one selected from phenylene, polyethyleneterephthalate (PET), polyimide (PI), polyamide (PAI), polyethylenenaphthalate (PEN), or polycarbonate (PC).

A refractive index of each of the filling layer FL1 and the lower filling layer FL2 for light having a first wavelength may be substantially the same as a refractive index of the patterned glass PG. Accordingly, in such an embodiment where the window WM includes the patterned glass PG, the window WM may achieve visibility of a certain level or higher. Here, the phrase “being substantially the same” used herein includes not only a case in which components are completely the same in physical terms such as refractive index or thickness, but also a case in which there is a difference within a margin of error generated during a process in spite of the same design. The first wavelength may be in a range about 500 nanometers (nm) to about 600 nm. In an embodiment, for example, the filling layer FL1, the lower filling layer FL2, and the patterned glass PG may have substantially the same refractive index as each other for green light.

The window adhesive layer W_AL may be disposed between the patterned glass PG and the window protective layer PL, and attach the window protective layer PL to the patterned glass PG. The window adhesive layer W_AL may include an optically transparent adhesive material. In an embodiment, for example, the window adhesive layer W_AL may include a pressure sensitive adhesive (PSA), an optical clear adhesive (OCA), or an optical clear resin (OCR).

FIG. 7 is a plan view illustrating a portion corresponding to a folding area of a display panel according to an embodiment of the invention.

Referring to FIG. 7, a folding area FA2 may include a folding non-emission area FNPXA and folding emission areas FPXA-R, FPXA-G and FPXA-B. The folding non-emission area FNPXA may refer to a non-emission area NPXA portion, which overlaps the folding area FA2 in a plan view (or in the third direction DR3), of the non-emission area NPXA illustrated in FIG. 5A. The folding emission areas FPXA-R, FPXA-G and FPXA-B may refer to emission areas PXA-R, PXA-G and PXA-B portions, which overlap the folding area FA2 in the plan view, of the emission areas PXA-R, PXA-G and PXA-B illustrated in FIG. 5A.

The folding emission areas FPXA-R, FPXA-G and FPXA-B may include first areas FPXA-G which emit first light, second areas FPXA-B which emit second light, and third areas FPXA-R which emit third light. The first to third light may be visible light having different wavelengths, respectively. In an embodiment, for example, the first light may be green light, the second light may be blue light, and the third light may be red light. However, an embodiment of the invention is not limited thereto, and the folding emission areas FPXA-R, FPXA-G and FPXA-B may emit light of colors other than the red light, the green light, and the blue light, the folding emission areas FPXA-R, FPXA-G and FPXA-B may the same surface area as each other, or the folding emission areas FPXA-R, FPXA-G and FPXA-B may be provided in a different surface area ratio from that illustrated herein. In an embodiment, for example, the folding emission areas FPXA-R, FPXA-G and FPXA-B may have a stripe structure in which the folding emission areas FPXA-R, FPXA-G and FPXA-B are alternately arranged in sequence. In the present disclosure, a “first area” may indicate any one of the folding emission areas FPXA-R, FPXA-G and FPXA-B, and a “peripheral area” may indicate the folding non-emission area FNPXA.

The first areas FPXA-G may be arranged along the second direction DR2 to constitute a first pixel row. The second areas FPXA-B and the third areas FPXA-R may be alternately disposed along the second direction DR2 to constitute a second pixel row. The first pixel row may be disposed apart from the second pixel row in the first direction DR1. Each of the first pixel row and the second pixel row may be provided in plurality. The first pixel rows and the second pixel rows may be arranged to alternate with each other along the first direction DR1. FIG. 7 illustrates an embodiment in which, in the folding area FA2, five first pixel rows each including the first areas FPXA-G are defined, and six second pixel rows each including the second areas FPXA-B and the third areas FPXA-R are defined. However, this is illustrative, and the window according to an embodiment of the invention may be variously designed as necessary without being limited.

FIG. 8A is a plan view illustrating a portion corresponding to a folding area of a window according to an embodiment of the invention. FIG. 8A illustrates, in greater detail, a patterned portion PP of the patterned glass PG (see FIG. 6A) according to an embodiment of the invention. FIG. 8B is a cross-sectional view illustrating a portion corresponding to a folding area of a window according to an embodiment of the invention. FIG. 8B is a cross-sectional view taken along cutting line II-II′ illustrated in FIG. 8A.

Referring to FIGS. 8A and 8B, in an embodiment, the patterned portion PP of the window may include a plurality of groove patterns GP. The plurality of groove patterns GP may include a plurality of first groove patterns GP1 provided in a top surface PG-F of the patterned portion PP, and a plurality of second groove patterns GP2 provided in a bottom surface PG-B of the patterned portion PP. In an embodiment where the folding axis FX2 (see FIG. 6A) extends in the first direction DR1, the first groove patterns GP1 may be arranged to be spaced apart from each other in the second direction DR2, and the second groove patterns GP2 may be arranged to be spaced apart from each other in the second direction DR2. The first groove patterns GP1 and the second groove patterns GP2 may be arranged to alternate with each other along the second direction DR2. FIG. 8A illustrates the groove patterns GP on a plane as including both the first groove patterns GP1 defined in the top surface PG-F and the second groove patterns GP2 defined in the bottom surface PG-B to show an embodiment of the invention in greater detail.

An arrangement of the plurality of groove patterns GP may be changed according to (or determined based on) an arrangement of folding emission areas FPXA-R, FPXA-G and FPXA-B. The groove patterns GP may be arranged in the second direction DR2 to correspond to any one emission area among the folding emission areas FPXA-R, FPXA-G and FPXA-B. In an embodiment, for example, the first groove patterns GP1 may be arranged to correspond to first areas FPXA-G. In the second direction DR2, the number of the groove patterns GP may be changed according to the number of the folding emission areas FPXA-R, FPXA-G and FPXA-B. In an embodiment, for example, the number of the groove patterns GP may be proportional to the number of the first areas FPXA-G included in a first pixel row in the second direction DR2.

The plurality of groove patterns GP satisfy Equation 1 or 2 below.

$$\frac{{N}_{a}}{{N}_{g}} = n \qquad [ Equation 1 ]$$

$$\frac{{N}_{a}}{{N}_{g}} = \frac{1}{n} \qquad [ Equation 2 ]$$

In Equations 1 and 2, N_{g} a denotes the number of the plurality of groove patterns GP arranged in the second direction DR2. For example, N_{g} may denote the number of the plurality of first groove patterns GP1 arranged in the second direction DR2, N_{g} may be the number of the plurality of second groove patterns GP2 arranged in the second direction DR2, or N_{g} a may be the number of the plurality of groove patterns GP1 and GP2 arranged in the second direction DR2.

In Equations 1 and 2, Nₐ denotes the number of the first areas arranged in the second direction DR2. For example, Nₐ may be the number of the first areas FPXA-G arranged in the second direction DR2. However, an embodiment is not limited thereto.

In Equations 1 and 2, n is an integer of 1 or greater. For example, n may be an integer of 1 to 100, or n may be an integer of 1 to 5. However, an embodiment is not limited thereto. As an example, FIGS. 8A and 8B illustrate a case in which, in Equation 1, N_{g} is 3, Nₐ is 3, and n is 1, but an embodiment is not limited thereto.

The patterned portion PP may include a wall portion LP, a lower portion BP, and an upper portion FP. The wall portion LP may indicate a portion defined between each of the first groove patterns GP1 and each of the second groove patterns GP2. The wall portion LP may have a shape extending in the third direction DR3. The lower portion BP may be a portion extending from a lower side of the wall portion LP in the second direction DR2, and the upper portion FP may be a portion extending from an upper side of the wall portion LP in the second direction DR2. The lower portion BP may include the top surface PG-F of the patterned portion PP, and the upper portion FP may include the bottom surface PG-B of the patterned portion PP. The lower portion BP and the upper portion FP may each be a portion which connects the wall portions LP spaced apart from each other in the second direction DR2. The lower portion BP and the upper portion FP may overlap the groove patterns GP on a plane.

The groove patterns GP, the lower portion BP, and the upper portion FP may be arranged to correspond to the first area FPXA-G, and the wall portion LP may be arranged to correspond to the second area FPXA-B. The wall portion LP may have a shape extending in the first direction DR1, and the wall portion LP may correspond to the second area FPXA-B or correspond to the third area FPXA-R in the first direction DR1. FIG. 8A illustrates an embodiment having a structure in which one groove pattern GP and one first area FPXA-G correspond to each other in a one-to-one manner (or are in a one-to-one correspondence with each other) in the second direction DR2, but an embodiment is not limited thereto. Although not illustrated, the patterned portion PP according to an embodiment of the invention may have a structure in which one groove pattern GP and n first areas FPXA-G included in one first pixel row correspond to each other in a one-to-n manner. Here, n may be an integer of 1 or greater, and an embodiment is not limited thereto.

FIGS. 9A, 10A, 11A and 12A are each a plan view illustrating a portion corresponding to a folding area of a window according to an embodiment of the invention. FIGS. 9A, 10A, 11A and 12A illustrate patterned portions PP-1, PP-2, PP-3 and PP-4 according to an embodiment each corresponding to the patterned portion described above with reference to FIG. 8A. FIGS. 9B, 10B, 11B and 12B are each a cross-sectional view illustrating a portion corresponding to a folding area of a window according to an embodiment of the invention. FIGS. 9B, 10B, 11B and 12B illustrate patterned portions PP-1, PP-2, PP-3 and PP-4 according to an embodiment each corresponding to the patterned portion described above with reference to FIG. 8B.

Referring to FIGS. 9A to 10B, in an embodiment, the number of groove patterns GP may be proportional to the number of second areas FPXA-B included in a second pixel row in the second direction DR2. The number of the groove patterns GP may be proportional to the number of third areas FPXA-R included in the second pixel row in the second direction DR2. Alternatively, the second areas FPXA-B and the third areas FPXA-R in the second pixel row in the second direction DR2 may be alternately arranged along the second direction DR2, and the number of the groove patterns GP may be proportional to a sum of the respective number of the second and third areas FPXA-B and FPXA-R included in the second pixel row. FIGS. 9A and 9B illustrate a case in which, in Equation 1 described above, N_{g} is 3, Nₐ is 3, and n is 1, as an example, and FIGS. 10A and 10B illustrate a case in which, in Equation 1 described above, N_{g} is 1.5, Nₐ is 3, and n is 2, as an example, but an embodiment is not limited thereto.

Referring to FIGS. 9A and 9B, in the patterned portion PP-1, the groove patterns GP may be arranged to correspond to the second area FPXA-B. The groove patterns GP may have a shape extending in the first direction DR1, and, in the first direction DR1, the groove patterns GP may correspond to the second area FPXA-B or correspond to the third area FPXA-R. A lower portion BP and an upper portion FP may each be arranged to correspond to the second area FPXA-B or the third area FPXA-R, and a wall portion LP may be arranged to correspond to a first area FPXA-G.

Referring to FIGS. 10A and 10B, in the patterned portion PP-2, the groove patterns GP may be arranged to correspond to the second area FPXA-B and the third area FPXA-R. A lower portion BP and an upper portion FP may each be arranged to correspond to the second area FPXA-B and the third area FPXA-R, and a wall portion LP may be arranged to correspond to a first area FPXA-G. As described above, FIG. 9A illustrates an embodiment having a structure in which one groove pattern GP and one second area FPXA-B or one third area FPXA-R correspond to each other in a one-to-one manner, but FIG. 1C0A illustrates a structure in which one groove pattern GP and two areas FPXA-B and FPXA-R included in one second pixel row correspond to each other in a one-to-two manner. Although not illustrated, the patterned portion according to an embodiment of the invention may have a structure in which one groove pattern GP and three areas FPXA-B, FPXA-R and FPXA-B included in one second pixel row correspond to each other in a one-to-three manner, and an embodiment is not limited thereto.

Referring to FIGS. 11A to 12B, the number of groove patterns GP may be proportional to the number of first areas FPXA-G included in a first pixel row in the second direction DR2, or the number of second areas FPXA-B included in a second pixel row in the second direction DR2. FIGS. 11A and 11B illustrate a case in which, in Equation 2 described above, N_{g} a is 6, Nₐ is 3, and n is 2, as an example, and FIGS. 12A and 12B illustrate a case in which, in Equation 1 described above, N_{g} is 3, Nₐ is 3, and n is 1, as an example. However, an embodiment is not limited thereto.

Referring to FIGS. 11A and 11B, in the patterned portion PP-3, the groove patterns GP may be arranged to correspond to the first area FPXA-G or correspond to the second area FPXA-B. In an embodiment, for example, first groove patterns GP1 may correspond to the first area FPXA-G, and second groove patterns GP2 may correspond to the second area FPXA-B. The second groove patterns GP2 may have a shape extending in the first direction DR1, and, in the first direction DR1, the second groove patterns GP2 may correspond to the second area FPXA-B or correspond to a third area FPXA-R. The first groove patterns GP1 may each have a first length in the second direction DR2 (or a first width), and the second groove patterns GP2 may each have a second length in the second direction DR2 (or a second width). The first length may correspond to (or be substantially the same as) a width of the first area FPXA-G, and the second length may correspond to (or be substantially the same as) a width of the second area FPXA-B or the third area FPXA-R. The first length may be substantially the same as a third length of the first area FPXA-G in the second direction DR2, and the second length may be substantially the same as a larger length among a length of the second area FPXA-B in the second direction DR2 or a length of the third area FPXA-R in the second direction DR2. In an embodiment, the first length may be less than the second length. A lower portion BP and an upper portion FP may each be arranged to correspond to the first area FPXA-G or correspond to the second area FPXA-B or the third area FPXA-R. A wall portion LP may be arranged to correspond to a peripheral area FNPXA.

Referring to FIGS. 12A and 12B, in the patterned portion PP-4, the groove patterns GP may be arranged to correspond to first to third areas FPXA-R, FPXA-G and FPXA-B. A lower portion BP and an upper portion FP may each be arranged to correspond to the first to third areas FPXA-R, FPXA-G and FPXA-B, and a wall portion LP may be arranged to correspond to the first area FPXA-G.

In a conventional display device, pattern glass includes a groove pattern for a folding operation to be easily performed, but light is relatively concentrated on a wall portion of the pattern glass in which the groove pattern is not defined. Accordingly, a moire phenomenon has occurred due to a difference in light distribution. In a display device according to an embodiment of the invention, a groove pattern of a window may be designed to correspond to the design of an emission area of a display panel, thereby securing high visibility. Specifically, in the display device according to an embodiment of the invention, a cycle of the number of the emission area in one direction may match an integer multiple of a cycle of the groove pattern (or a wall portion) in the one direction, thereby resolving the occurrence of the moire phenomenon. For example, in a case where a cycle of the number of specific emission areas in one direction matches a cycle of the wall portion in the one direction, light may be concentratively emitted for a specific color, and in this case, the phenomenon may be resolved (substantially reduced or effectively prevented) by a quantitative adjustment in a light emitting element, or the like. Alternatively, in a case where a cycle of the number of non-emission areas in one direction matches a cycle of the wall portion in the one direction, and a width itself of the groove pattern matches a red, blue, or green emission area, the light distribution may become uniform, thereby resolving the occurrence of the moire phenomenon. In another embodiment, for example, where a cycle of the number of the non-emission areas in one direction matches a cycle of the wall portion in the one direction, and all the red, blue, and green emission areas are included in one groove pattern, the light distribution may become uniform, thereby resolving the occurrence of the moire phenomenon. Accordingly, the display device according to an embodiment of the invention may have high visibility to improve reliability.

In the display device according to embodiments of the invention, the groove pattern of the window may be designed to correspond to the design of the emission area of the display panel, thereby resolving the user visibility issue likely to occur due to the patterned portion of the pattern glass.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising a folding area foldable around a folding axis on a plane, and a non-folding area adjacent to the folding area, the display device comprising:
a display panel comprising a plurality of light emitting elements; and
a window disposed on the display panel and comprising a patterned glass,
wherein the patterned glass comprises:
a patterned portion corresponding to the folding area and having one surface in which a plurality of first groove patterns extending in a first direction and arranged in a second direction perpendicular to the first direction are defined; and
a non-patterned portion adjacent to the patterned portion and corresponding to the non-folding area,
wherein the folding area comprises a plurality of first areas corresponding to the plurality of light emitting elements, respectively, and arranged in the second direction, and a peripheral area adjacent to the plurality of first areas, and
the patterned glass satisfies one of the following Equations:
$$\frac{{N}_{a}}{{N}_{g}} = n and \frac{{N}_{a}}{{N}_{g}} = \frac{1}{n} ,$$
wherein
N_{g} denotes a number of the plurality of first groove patterns arranged in the second direction,
Nₐ denotes a number of the plurality of first areas arranged in the second direction, and
n is an integer of 1 or greater.

2. The display device of claim 1, wherein the window further comprises a filling layer filled in the first groove patterns.

3. The display device of claim 1, wherein the plurality of first groove patterns correspond to the plurality of first areas, respectively.

4. The display device of claim 1, wherein the plurality of first areas emit first light,
wherein the folding area further comprises a plurality of second areas which emits second light, and a plurality of third areas which emits third light,
wherein the peripheral area surrounds each of the plurality of first areas, the plurality of second areas, and the plurality of third areas.

5. The display device of claim 4, wherein the plurality of first groove patterns corresponds to the plurality of second areas, respectively, or corresponds to the plurality of third areas, respectively.

6. The display device of claim 4, wherein the folding area comprises:
a first pixel row comprising the plurality of first areas arranged in the second direction; and
a second pixel row in which the plurality of second areas and the plurality of third areas are arranged alternately with each other in the second direction, wherein the second pixel row is spaced apart from the first pixel row in the second direction.

7. The display device of claim 1, wherein the plurality of first groove patterns are defined in a top surface of the patterned portion, and
a plurality of second groove patterns extending in the first direction and arranged in the second direction are defined in a bottom surface of the patterned portion.

8. The display device of claim 7, wherein the window further comprises a lower filling layer filled in the second groove patterns.

9. The display device of claim 7, wherein each of the plurality of first groove patterns has a first length in the second direction, and each of the plurality of second groove patterns has a second length in the second direction,
wherein the first length is less than the second length.

10. The display device of claim 9, wherein a third length of each of the plurality of first areas in the second direction is substantially the same as the first length.

11. The display device of claim 7, wherein the plurality of first groove patterns and the plurality of second groove patterns are arranged alternately with each other in the second direction.

12. The display device of claim 11, wherein the patterned portion comprises:
a wall portion defined between a first groove pattern of the plurality of first groove patterns and a second groove pattern of the plurality of second groove patterns, which are adjacent to each other;
a lower portion extending from a lower side of the wall portion in the second direction and comprising the bottom surface of the patterned portion; and
an upper portion extending from an upper side of the wall portion in the second direction and comprising the top surface of the patterned portion.

13. The display device of claim 12, wherein the wall portion corresponds to the plurality of first areas.

14. The display device of claim 12, wherein the wall portion corresponds to the peripheral area.

15. A display device comprising a folding area foldable around a folding axis on a plane, and a non-folding area adjacent to the folding area, the display device comprising:
a display panel comprising a light emitting element; and
a window disposed on the display panel and comprising a patterned glass,
wherein the folding area comprises a folding emission area corresponding to the light emitting element, and a folding non-emission area adjacent to the folding emission area,
wherein the patterned glass comprises:
a patterned portion corresponding to the folding area, and having a top surface in which a plurality of first groove patterns are defined, and a bottom surface in which a plurality of second groove patterns are defined; and
a non-patterned portion adjacent to the patterned portion and corresponding to the non-folding area,
wherein the patterned portion comprises:
a wall portion defined between a first groove pattern of the plurality of first groove patterns and a second groove pattern of the plurality of second groove patterns, which are adjacent to each other;
a lower portion extending from a lower side of the wall portion in one direction and comprising the bottom surface of the patterned portion; and
an upper portion extending from an upper side of the wall portion in the one direction and comprising the top surface of the patterned portion,
wherein the wall portion corresponds to the folding emission area or corresponds to the folding non-emission area.

16. The display device of claim 15, wherein the folding emission area comprises a plurality of first areas which emits first light, a plurality of second areas which emits second light, and a plurality of third areas which emits third light.

17. The display device of claim 16, wherein the wall portion corresponds to the plurality of second areas or the plurality of third areas, and
the lower portion, the upper portion, the plurality of first groove patterns, and the plurality of second groove patterns correspond to the plurality of first areas.

18. The display device of claim 16, wherein the wall portion corresponds to the plurality of first areas, and
the lower portion, the upper portion, the plurality of first groove patterns, and the plurality of second groove patterns correspond to the plurality of second areas or the plurality of third areas.

19. The display device of claim 16, wherein the wall portion corresponds to the folding non-emission area, and
the lower portion, the upper portion, the plurality of first groove patterns, and the plurality of second groove patterns correspond to the plurality of first areas, the plurality of second areas, or the plurality of third areas.

20. An electronic device comprising:
a display device comprising a folding area foldable around a folding axis on a plane, and a non-folding area adjacent to the folding area; and
a power module supplying power to the display device, wherein the display device comprises:
a display panel comprising a plurality of light emitting elements; and
a window disposed on the display panel and comprising a patterned glass,
wherein the patterned glass comprises:
a patterned portion corresponding to the folding area and having one surface in which a plurality of first groove patterns extending in a first direction and arranged in a second direction perpendicular to the first direction are defined; and
a non-patterned portion adjacent to the patterned portion and corresponding to the non-folding area,
wherein the folding area comprises a plurality of first areas corresponding to the plurality of light emitting elements, respectively, and arranged in the second direction, and a peripheral area adjacent to the plurality of first areas, and
the patterned glass satisfies one of the following Equations:
$$\frac{{N}_{a}}{{N}_{g}} = n and \frac{{N}_{a}}{{N}_{g}} = \frac{1}{n} ,$$
wherein
N_{g} denotes a number of the plurality of first groove patterns arranged in the second direction,
Nₐ denotes a number of the plurality of first areas arranged in the second direction, and
n is an integer of 1 or greater.
